(19) United States
(12) Patent Application Publication
(10) Pub. No.: US 2026/0297320 A1
(43) Pub. Date: Oct. 1, 2026

(54) CURABLE RESIN COMPOSITION, DRY FILM, CURED PRODUCT, AND ELECTRONIC COMPONENT

(71) Applicant: TAIYO HOLDINGS CO., LTD., Saitama (JP)

(72) Inventors: Kyosuke HAMASHIMA, Saitama (JP); Daichi OKAMOTO, Saitama (JP); Daisuke SHIBATA, Saitama (JP)

(21) Appl. No.: 19/571,976

(22) Filed: Mar. 19, 2026

(30) Foreign Application Priority Data
Mar. 25, 2025 (JP) 2025-050453
Mar. 13, 2026 (JP) 2026-040967

(51) Int. Cl. C08L 51/08; C08K 3/36

(52) U.S. Cl. CPC C08L 51/08; C08K 3/36; C08K 2201/005; C08L 2203/16

(57) ABSTRACT

A curable resin composition contains an alkali-soluble resin; a thermosetting resin; a photopolymerization initiator; an inorganic filler; and a colorant. A 10 μm-thick cured product of the curable resin composition has a transmittance at a wavelength of 405 nm of 60% to 75%, and a transmittance at a wavelength of 650 nm of 45% to 62%.

### CROSS REFERENCE TO RELATED APPLICATIONS

This application claims benefit of priority to Japanese Patent Application 2025-050453, filed Mar. 25, 2025 and Japanese Patent Application 2026-040967, filed Mar. 13, 2026, the entire content of which is incorporated herein by reference.

### BACKGROUND

### Technical Field

The present disclosure relates to a curable resin composition, a dry film, a cured product, and an electronic component.

### Background Art

In the production of a printed wiring board, a curable resin composition is generally used for forming a permanent film such as a solder resist, and dry film-type compositions and liquid compositions have been developed as such curable resin compositions. Among these compositions, alkali-developable curable resin compositions using a dilute alkaline aqueous solution as a developer have become mainstream in consideration of environmental issue, and several composition systems have been proposed. JP 2011-013622 A discloses a photosensitive resin composition that contains a resin having at least one carboxyl group and ethylenically unsaturated group in the molecule, a photopolymerizable monomer, a photopolymerization initiator, an epoxy compound, and a silica filler. JP 2021-170054 A discloses a curable resin composition that contains an alkali-soluble resin, a photopolymerization initiator, a thermosetting resin, and a colorant.

### SUMMARY

One aspect of the present disclosure provides a curable resin composition. The curable resin composition contains an alkali-soluble resin, a thermosetting resin, a photopolymerization initiator, an inorganic filler, and a colorant. A 10 μm-thick cured product of the curable resin composition has a transmittance at a wavelength of 405 nm of 60% to 75%, and a transmittance at a wavelength of 650 nm of 45% to 62%.

According to one aspect of the present disclosure, a curable resin composition having favorable thin-film resolution and thick-film resolution may be provided.

### DETAILED DESCRIPTION

In the present specification, when there are plural substances that correspond to a component of a composition, an indicated amount of the component contained in the composition refers to, unless otherwise specified, a total amount of the plural substances existing in the composition. Further, as upper and lower limits of a numerical range described in the present specification, values exemplified for the numerical range may be selected and combined as appropriate. The term “(meth)acrylate” used herein is a general term that encompasses an acrylate, a methacrylate, and a mixture thereof, and the same applies to other similar expressions. Further, the term “solid content” used herein refers to a residue obtained by removing volatile components (e.g., an organic solvent) from a composition or its components. Embodiments of the present disclosure will now be described in detail. It is noted here, however, that the below-described embodiments are merely examples of a curable resin composition, a dry film, a cured product, and an electronic component that embody the technical ideas of the present disclosure, and the present disclosure is not limited to the below-described curable resin composition, dry film, cured product, and electronic component.

With the miniaturization and performance enhancement of electronic devices, pin densification and pitch reduction are advancing, solder resists are expected to exhibit small-diameter opening property. In addition, as substrates have become thinner, solder resists are also expected to be formed into thinner films. Therefore, solder resists are expected to exhibit small-diameter opening property even in thin films.

When a smooth solder resist is formed on the surface of a substrate in which a copper circuit has been formed on a base material, the solder resist formed on the copper is relatively a thin film, while the solder resist formed on the base material is relatively a thick film. The resolution of the thin film portion on the copper may be deteriorated by reflected light of the copper and scattered light of an inorganic filler. The reflected light and the scattered light are believed to be suppressed by darkening the solder resist. However, darkening may prevent light from sufficiently reaching a deep part of the thick film portion on the base material during exposure, causing deterioration of the deep curing property and reduction in the resolution of the thick-film solder resist on the base material.

Therefore, an object of one aspect of the present disclosure is to provide a curable resin composition having favorable thin-film resolution and thick-film resolution.

The present disclosure encompasses the following aspects.

Aspect 1: A curable resin composition containing an alkali-soluble resin, a thermosetting resin, a photopolymerization initiator, an inorganic filler, and a colorant, wherein a 10 μm-thick cured product of the curable resin composition has a transmittance at a wavelength of 405 nm of 60% to 75%, and a transmittance at a wavelength of 650 nm of 45% to 62%.

Aspect 2: The curable resin composition according to Aspect 1, wherein the inorganic filler has a volume-average particle size of 0.1 μm or less.

Aspect 3: The curable resin composition according to Aspect 1 or Aspect 2, wherein a content percentage of the inorganic filler, calculated on a solid content basis, is 10% by mass to 50% by mass based on the total solid content of the curable resin composition.

Aspect 4: The curable resin composition according to any one of Aspect 1 to Aspect 3, wherein the inorganic filler contains a silicon oxide.

Aspect 5: The curable resin composition according to Aspect 4, wherein a content percentage of the silicon oxide in the inorganic filler is 70% by mass to 100% by mass.

Aspect 6: The curable resin composition according to any one of Aspect 1 to Aspect 5, wherein a content percentage of the colorant, calculated on a solid content basis, is 0.70% by mass to 1.10% by mass based on the total solid content of the curable resin composition.

Aspect 7: The curable resin composition according to any one of Aspect 1 to Aspect 6, wherein a mass ratio of the content of the colorant to the content of the inorganic filler, each content being calculated on a solid content basis, is 0.015 to 0.05.

Aspect 8: A dry film, including a first film, and a resin layer laminated on the first film, the resin layer being a dry coating film of the curable resin composition according to any one of Aspect 1 to Aspect 7.

Aspect 9: A cured product of the curable resin composition according to any one of Aspect 1 to Aspect 7, or a cured product of the resin layer of the dry film according to Aspect 8.

Aspect 10: An electronic component, including the cured product according to Aspect 9.

According to one aspect of the present disclosure, a curable resin composition having favorable thin-film resolution and thick-film resolution can be provided. The term “thin-film resolution” used herein particularly refers to thin-film small-diameter resolution, i.e., small-diameter opening property in the form of a thin film.

### Curable Resin Composition

The curable resin composition may contain an alkali-soluble resin, a thermosetting resin, a photopolymerization initiator, an inorganic filler, and a colorant. Further, when the curable resin composition forms a 10 μm-thick cured product, this cured product may have a transmittance at a wavelength of 405 nm of 60% to 75%, and a transmittance at a wavelength of 650 nm of 45% to 62%.

The cured product of the curable resin composition has a transmittance at a wavelength of 405 nm and at a wavelength of 650 nm in the respective specified ranges; therefore, when the curable resin composition forms a smooth coating film on the surface of a substrate in which a copper circuit has been formed on a base material, the thin-film resolution on copper and the thick-film resolution on the base material may both be achieved at high levels. By controlling the transmittance at a wavelength of 650 nm, which is in the visible light region, to be 45% to 62%, it is believed that the coating film is darkened, and the absorbance of the reflected light of copper and the scattered light of the inorganic filler during exposure is increased, as a result of which halation is inhibited, and the thin-film resolution on copper is improved. Further, by controlling the transmittance at a wavelength of 405 nm, which is in the ultraviolet region and contributes to photocuring, to be 60% to 75%, even if the film is thick, the light required for photocuring may sufficiently reach a deep part during exposure. As a result, good deep curing property is obtained, so that the thick-film resolution on the base material is believed to be improved. In the present specification, a “thin film” refers to a film with a thickness of about 10 μm, for example, a film with a thickness of 6 μm to 14 μm, or 8 μm to 12 μm, and a “thick film” refers to a film with a thickness of about 20 μm, for example, a film with a thickness of 16 μm to 24 μm, or 18 μm to 22 μm.

The transmittance of the cured product at a wavelength of 405 nm and at a wavelength of 650 nm can be adjusted by appropriately selecting the content percentages, the types, and the particle sizes of the colorant, the inorganic filler, and the like that are contained in the curable resin composition, as well as the photopolymerization initiator and the like. For example, by adopting the below-described preferred modes for the content percentages, the types, and the particle sizes of the colorant, the inorganic filler, and the like that are contained in the curable resin composition, as well as the photopolymerization initiator and the like, the transmittance of the 10 μm-thick cured product at a wavelength of 405 nm and at a wavelength of 650 nm can be adjusted to be in the above-described respective ranges.

The 10 μm-thick cured product used for the measurement of transmittance can be obtained by the following procedure. First, the curable resin composition is applied onto a 1 mm-thick glass substrate using an applicator such that the resulting resin layer has a post-curing thickness of 10 μm, and the thus applied curable resin composition is subsequently dried at 80° C. for 20 minutes to form a resin layer. Alternatively, a resin layer is formed by laminating a dry film, which is provided with a resin layer having a post-curing thickness of 10 μm, on a 1 mm-thick glass substrate, and subsequently peeling off a carrier film. Thereafter, the resin layer is irradiated with ultraviolet rays in a UV conveyor furnace at a cumulative exposure dose of 1,000 mJ/cm², and then heat-cured at 160° C. for 60 minutes, whereby the 10 μm-thick cured product can be formed.

The transmittance of the cured product can be measured by the following procedure. Using a UV-visible spectrophotometer and an integrating sphere apparatus (UV/VIS/NIR spectrometer V-570, manufactured by JASCO Corporation), the baseline in a range of 300 nm to 850 nm is measured, and the transmittance of the cured product is subsequently measured. In the measurement, the scanning speed is set at 400 nm/min, and the scanning interval is set at 1 nm.

From the standpoint of the thick-film resolution, the transmittance of the 10 μm-thick cured product at a wavelength of 405 nm may be, for example, 60% to 75%, preferably 63% to 70%, more preferably 66% or higher but lower than 70%, still more preferably 67% to 69%, or higher than 67% but lower than 69%. When this transmittance is equal to or higher than the above-described lower limit, light tends to reach a deep part during exposure. As a result, the deep curing property is enhanced, so that the thick-film resolution is improved. Meanwhile, when this transmittance is equal to or lower than the above-described upper limit, the thin-film resolution or the masking property is improved.

From the standpoint of the thin-film resolution, e.g., small-diameter opening property in the form of a thin film, the transmittance of the 10 μm-thick cured product at a wavelength of 650 nm may be, for example, 45% to 62%, 45% to 61%, or 45% to 60%, preferably 49% to 60%, more preferably 50% to 60%, still more preferably 52% to 60%, 55% to 60%, or 58% to 60%. When this transmittance is equal to or lower than the above-described upper limit, halation caused by the reflected light of copper and the scattered light of the inorganic filler during exposure is inhibited, so that the thin-film resolution tends to be improved.

Further, a lower transmittance of light at a wavelength of 650 nm tends to lead to an increased absorbance of light at a wavelength of 650 nm and a further improvement in the masking property against a wavelength of 650 nm. A wavelength of 650 nm exhibits an orange to red color; therefore, an improvement in the masking property against a wavelength of 650 nm tends to make it easier to hide the color of copper. In other words, the lower the transmittance of light at a wavelength of 650 nm, the masking property of a copper circuit on a substrate tends to be further improved. A high masking property of a copper circuit on a substrate is advantageous in that it may prevent false detections in an appearance inspection of a printed wiring board, such as a visual inspection, or an inspection using a substrate appearance inspection (automated optical inspection: AOI) device. Therefore, by reducing the transmittance of the 10 μm-thick cured product at a wavelength of 650 nm to, for example, the above-described upper limit or lower, not only the masking property of a copper circuit may be improved, but also false detections in an appearance inspection of a printed wiring board may be prevented.

### Alkali-Soluble Resin

The curable resin composition may contain an alkali-soluble resin. By incorporating an alkali-soluble resin into the curable resin composition, alkali developability may be imparted to the curable resin composition.

Examples of the alkali-soluble resin include: compounds having two or more phenolic hydroxy groups; carboxy group-containing resins; compounds having a phenolic hydroxy group and a carboxy group; and compounds having two or more thiol groups. Thereamong, from the standpoint of developability, a carboxy group-containing resin is preferred.

From the standpoint of photocurability and resistance to development, the carboxy group-containing resin is preferably a carboxy group-containing photosensitive resin having an ethylenically unsaturated group in the molecule in addition to a carboxy group. The ethylenically unsaturated group is preferably derived from acrylic acid or methacrylic acid, or a derivative thereof.

Specific examples of the carboxy group-containing resin include the following. The carboxy group-containing resin may be used singly, or in combination of two or more kinds thereof.

(1) A carboxy group-containing photosensitive resin obtained by allowing (meth)acrylic acid to react with a polyfunctional (solid) epoxy resin having two or more functional groups, and adding a dibasic acid anhydride such as phthalic anhydride, tetrahydrophthalic anhydride, or hexahydrophthalic anhydride, to a hydroxy group in a side chain of the resultant;

(2) A carboxy group-containing photosensitive resin obtained by allowing (meth)acrylic acid to react with a polyfunctional (solid) epoxy resin, which is obtained by further epoxidizing a hydroxy group of a bifunctional (solid) epoxy resin with epichlorohydrin, and then adding a dibasic acid anhydride to the resulting hydroxy group;

(3) A carboxy group-containing photosensitive resin obtained by allowing an epoxy compound having two or more epoxy groups in one molecule to react with a compound having at least one alcoholic hydroxy group and one phenolic hydroxy group in one molecule and an unsaturated group-containing monocarboxylic acid such as (meth)acrylic acid, and then allowing the alcoholic hydroxy group of the thus obtained reaction product to react with a polybasic acid anhydride such as maleic anhydride, tetrahydrophthalic anhydride, trimellitic anhydride, pyromellitic anhydride, or adipic anhydride;

(4) A carboxy group-containing photosensitive resin obtained by allowing an unsaturated group-containing monocarboxylic acid such as (meth)acrylic acid to react with a reaction product, which is obtained by a reaction between a compound having two or more phenolic hydroxy groups in one molecule (e.g., bisphenol A, bisphenol F, bisphenol S, a novolac-type phenol resin, a novolac-type cresol resin, poly-p-hydroxystyrene, a condensation product of naphthol and an aldehyde, or a condensation product of dihydroxynaphthalene and an aldehyde) and an alkylene oxide (e.g., ethylene oxide or propylene oxide), and then allowing the resulting reaction product to react with a polybasic acid anhydride;

(5) A carboxy group-containing photosensitive resin obtained by allowing an unsaturated group-containing monocarboxylic acid to react with a reaction product, which is obtained by a reaction between a compound having two or more phenolic hydroxy groups in one molecule and a cyclic carbonate compound such as ethylene carbonate or propylene carbonate, and then allowing the resulting reaction product to react with a polybasic acid anhydride;

(6) A carboxy group-containing photosensitive resin obtained by adding a compound having a cyclic ether group and a (meth)acryloyl group in one molecule to a terminal carboxy group-containing urethane resin that is obtained by allowing a terminal of an urethane resin, which is generated by a polyaddition reaction between a diisocyanate compound (e.g., an aliphatic diisocyanate, a branched aliphatic diisocyanate, an alicyclic diisocyanate, or an aromatic diisocyanate) and a diol compound (e.g., a polycarbonate-based polyol, a polyether-based polyol, a polyester-based polyol, a polyolefin-based polyol, an acrylic polyol, a bisphenol A-type alkylene oxide adduct diol, or a compound having a phenolic hydroxy group and an alcoholic hydroxy group), to react with an acid anhydride;

(7) A carboxy group-containing urethane resin having a (meth)acrylated terminal, which is obtained by adding a compound having one hydroxy group and one or more (meth)acryloyl groups in one molecule, such as hydroxyalkyl (meth)acrylate, during the synthesis of a carboxy group-containing urethane resin by a polyaddition reaction of a diisocyanate, a carboxy group-containing dialcohol compound (e.g. dimethylol propionic acid or dimethylol butanoic acid), and a diol compound;

(8) A carboxy group-containing urethane resin having a (meth)acrylated terminal, which is obtained by adding a compound having one isocyanate group and one or more (meth)acryloyl groups in the molecule, such as an equimolar reaction product of isophorone diisocyanate and pentaerythritol triacrylate, during the synthesis of a carboxy group-containing urethane resin by a polyaddition reaction of a diisocyanate, a carboxy group-containing dialcohol compound, and a diol compound;

(9) A carboxy group-containing photosensitive resin obtained by adding a compound having a cyclic ether group and a (meth)acryloyl group in one molecule to a carboxy group-containing resin obtained by copolymerization of an unsaturated carboxylic acid, such as (meth)acrylic acid, and an unsaturated group-containing compound such as styrene, α-methylstyrene, a lower alkyl (meth)acrylate, or isobutylene;

(10) A carboxy group-containing photosensitive resin obtained by further adding a compound having one epoxy group and one or more (meth)acryloyl groups in one molecule, such as glycidyl (meth)acrylate or α-methylglycidyl (meth)acrylate, to a carboxy group-containing polyester resin obtained by allowing a dicarboxylic acid such as adipic acid, phthalic acid, or hexahydrophthalic acid to react with a polyfunctional oxetane resin, and then adding a dibasic acid anhydride to the resulting primary hydroxy group; and

(11) A carboxy group-containing photosensitive resin obtained by adding a compound having a cyclic ether group and a (meth)acryloyl group in one molecule to any one of the carboxy group-containing photosensitive resins described in the above (1) to (5), (7), (8), and (10).

The above-described carboxy group-containing resin having an ethylenically unsaturated group has a large number of carboxy groups in a side chain of the backbone polymer and, therefore, may be developed with an aqueous alkaline solution.

The carboxy group-containing resin may have an acid value of, for example, 30 mgKOH/g to 200 mgKOH/g, preferably 40 mgKOH/g to 150 mgKOH/g, more preferably 45 mgKOH/g to 120 mgKOH/g, still more preferably 60 mgKOH/g to 100 mgKOH/g. When the acid value of the carboxy group-containing resin is equal to or more than the above-described lower limit (e.g., 30 mgKOH/g or more), good alkali developability is obtained. Meanwhile, when the acid value of the carboxy group-containing resin is equal to or less than the above-described upper limit (e.g., 200 mgKOH/g or less), dissolution of an exposed part by a developer may be inhibited; therefore, lines are prevented from being thinner than necessary and, depending on the case, exposed and non-exposed parts are prevented from being indistinctively dissolved and detached by a developer, so that a patterned resist may be drawn in a favorable manner.

The weight-average molecular weight Mw of the carboxy group-containing resin varies depending on the resin skeleton; and, it may be, for example, 500 to 150,000, preferably 800 to 100,000, 1,000 to 50,000, 1,500 to 10,000, or 1,800 to 5,000. When the weight-average molecular weight is equal to or more than the above-described lower limit, good tack-free performance is obtained, and the resulting coating film after exposure has good moisture resistance, so that a reduction in the film is inhibited during development, and deterioration of the resolution tends to be inhibited. When the weight-average molecular weight is equal to or less than the above-described upper limit, good developability and good storage stability tend to be obtained. In the present specification, the value of the weight-average molecular weight refers to a value measured by a gel permeation chromatography (GPC) method (in terms of polystyrene).

The content percentage of the alkali-soluble resin, calculated on a solid content basis, may be, for example, 20% by mass to 60% by mass, preferably 25% by mass to 55% by mass, more preferably 30% by mass to 50% by mass, still more preferably 35% by mass to 45% by mass, based on the total solid content of the curable resin composition. When the content percentage of the alkali-soluble resin is in the above-described range, superior alkali developability may be provided.

### Thermosetting Resin

The curable resin composition may contain a thermosetting resin. By incorporating a thermosetting resin into the curable resin composition, the heat resistance and the electrical insulation of the resin composition may be improved.

Examples of the thermosetting resin include epoxy resins, oxetane resins, melamine resins, and silicone resins. These resins may be used singly, or in combination of two or more kinds thereof. Thereamong, from the standpoint of low-temperature curability, the thermosetting resin may contain preferably at least one selected from the group consisting of epoxy resins and oxetane resins, more preferably at least an epoxy resin.

Examples of the epoxy resin include bisphenol A-type epoxy resins, bisphenol S-type epoxy resins, bisphenol F-type epoxy resins, phenol novolac-type epoxy resins, cresol novolac-type epoxy resins, and alicyclic epoxy resin.

Specific examples of the epoxy resin include, but are not limited to: bisphenol A-type epoxy resins, such as jER828, jER834, jER1001, and jER1004, which are manufactured by Mitsubishi Chemical Corporation, EPICLON 840, EPICLON 850, EPICLON 1050, EPICLON 2055, and N-870, which are manufactured by DIC Corporation, EPOTOHTO YD-011, YD-013, YD-127, and YD-128, which are manufactured by NIPPON STEEL Chemical & Material Co., Ltd., D.E.R.317, D.E.R.331, D.E.R.661, and D.E.R.664, which are manufactured by Dow Chemical Japan, Ltd., SUMI-EPOXY ESA-011, ESA-014, ELA-115, and ELA-128, which are manufactured by Sumitomo Chemical Co., Ltd., and A.E.R.330, A.E.R.331, A.E.R.661, and A.E.R.664, which are manufactured by Asahi Kasei Corporation; brominated epoxy resins, such as jERYL 903 manufactured by Mitsubishi Chemical Corporation, EPICLON 152 and EPICLON 165, which are manufactured by DIC Corporation, EPOTOHTO YDB-400 and YDB-500, which are manufactured by NIPPON STEEL Chemical & Material Co., Ltd., D.E.R.542 manufactured by Dow Chemical Japan, Ltd., SUMI-EPOXY ESB-400 and ESB-700, which are manufactured by Sumitomo Chemical Co., Ltd., and A.E.R.711 and A.E.R.714, which are manufactured by Asahi Kasei Corporation; novolac-type epoxy resins, such as jER152 and jER154, which are manufactured by Mitsubishi Chemical Corporation, D.E.N.431 and D.E.N.438, which are manufactured by Dow Chemical Japan, Ltd., EPICLON N-730, EPICLON N-770, and EPICLON N-865, which are manufactured by DIC Corporation, EPOTOHTO YDCN-701 and YDCN-704, which are manufactured by NIPPON STEEL Chemical & Material Co., Ltd., EPPN-201, EOCN-1025, EOCN-1020, EOCN-104S, RE-306, and NC-3000, which are manufactured by Nippon Kayaku Co., Ltd., SUMI-EPOXY ESCN-195X and ESCN-220, which are manufactured by Sumitomo Chemical Co., Ltd., A.E.R. ECN-235 and ECN-299, which are manufactured by Asahi Kasei Corporation, YDCN-700-2, YDCN-700-3, YDCN-700-5, YDCN-700-7, YDCN-700-10, YDCN-704, and YDCN-704A, which are manufactured by NIPPON STEEL Chemical & Material Co., Ltd., and EPICLON N-680, N-690, and N-695, which are manufactured by DIC Corporation (all of which are trade names); bisphenol F-type epoxy resins, such as EPICLON 830 manufactured by DIC Corporation, jER807 manufactured by Mitsubishi Chemical Corporation, and EPOTOHTO YDF-170, YDF-175, and YDF-2004, which are manufactured by NIPPON STEEL Chemical & Material Co., Ltd.; hydrogenated bisphenol A-type epoxy resins, such as EPOTOHTO ST-2004, ST-2007, and ST-3000, which are manufactured by NIPPON STEEL Chemical & Material Co., Ltd.; glycidylamine-type epoxy resins, such as jER604 manufactured by Mitsubishi Chemical Corporation, EPOTOHTO YH-434 manufactured by NIPPON STEEL Chemical & Material Co., Ltd., and SUMI-EPOXY ELM-120 manufactured by Sumitomo Chemical Co., Ltd.; hydantoin-type epoxy resins; alicyclic epoxy resins, such as CELLOXIDE 2021 manufactured by Daicel Corporation; trihydroxyphenyl methane-type epoxy resins, such as YL-933 manufactured by Mitsubishi Chemical Corporation, and T.E.N., EPPN-501, and EPPN-502, which are manufactured by Dow Chemical Japan, Ltd.; bixylenol-type or biphenol-type epoxy resins and mixtures thereof, such as YL-6056, YX-4000, and YL-6121, which are manufactured by Mitsubishi Chemical Corporation; bisphenol S-type epoxy resins, such as EBPS-200 manufactured by Nippon Kayaku Co., Ltd., EPX-30 manufactured by ADEKA Corporation, and EXA-1514 manufactured by DIC Corporation; bisphenol A novolac-type epoxy resins, such as jER157S manufactured by Mitsubishi Chemical Corporation; tetraphenylolethane-type epoxy resins, such as jERYL-931 manufactured by Mitsubishi Chemical Corporation; heterocyclic epoxy resins, such as TEPIC manufactured by Nissan Chemical Corporation; diglycidyl phthalate resins, such as BLEMMER DGT manufactured by NOF Corporation; tetraglycidyl xylenoylethane resins, such as ZX-1063 manufactured by NIPPON STEEL Chemical & Material Co., Ltd.; naphthalene group-containing epoxy resins, such as ESN-190 and ESN-360, which are manufactured by NIPPON STEEL Chemical & Material Co., Ltd., and HP-4032, EXA-4750, and EXA-4700, which are manufactured by DIC Corporation; epoxy resins having a dicyclopentadiene skeleton, such as HP-7200 and HP-7200H manufactured by DIC Corporation; glycidyl methacrylate copolymer-based epoxy resins, such as CP-50S and CP-50M manufactured by NOF Corporation; cyclohexylmaleimide-glycidyl methacrylate copolymer epoxy resins; and CTBN-modified epoxy resins (e.g., YR-102 and YR-450, manufactured by NIPPON STEEL Chemical & Material Co., Ltd.). Thereamong, bisphenol A-type epoxy resins, heterocyclic epoxy resins, and mixtures thereof are preferred because of their excellent discoloration resistance in particular. These epoxy resins may be used singly, or in combination of two or more kinds thereof.

The epoxy equivalent of the epoxy resin may be, for example, 80 g/eq to 1,000 g/eq, preferably 90 g/eq to 500 g/eq, more preferably 100 g/eq to 400 g/eq, or 150 g/eq to 300 g/eq.

The content of the thermosetting resin in the curable resin composition, calculated on a solid content basis, may be, for example, 20 parts by mass to 70 parts by mass, preferably 30 parts by mass to 60 parts by mass, more preferably 35 parts by mass to 55 parts by mass, still more preferably 40 parts by mass to 50 parts by mass, based on 100 parts by mass of the solid content of the alkali-soluble resin. When the content of the thermosetting resin is in the above-described range, the curable resin composition tends to be excellent in storage stability, strength of its cured product, and the like.

### Photopolymerization Initiator

The curable resin composition may contain a photopolymerization initiator. Examples of the photopolymerization initiator include benzophenone derivatives, thioxanthone derivatives, oxime ester compounds, benzoin derivatives, acetophenone derivatives, α-aminoacetophenone derivatives, hydroxyacetophenone derivatives, anthraquinone derivatives, acylphosphine oxide compounds, and titanocene compounds. The photopolymerization initiator may contain at least one selected from the group consisting of these derivatives and compounds, preferably at least one selected from the group consisting of acylphosphine oxide compounds and titanocene compounds. In the curable resin composition, these photopolymerization initiators may be contained singly, or in combination of two or more kinds thereof.

Examples of the benzophenone derivatives include benzophenone, 4-phenylbenzophenone, 4,4′-bis-diethylaminobenzophenone, methyl-o-benzoyl benzoate, 4-(4-methylphenylthio)benzophenone, 1-[4-(4-benzoylphenylsulfanyl)phenyl]-2-methyl-2-(4-methylphenylsulfonyl) propan-1-one, 4,4′-dichlorobenzophenone, hydroxybenzophenone, 4-benzoyl-4′-methyldiphenyl sulfide, 3,3′,4,4′-tetra(t-butylperoxycarbonyl)benzophenone, and 3,3′-dimethyl-4-methoxybenzophenone.

Examples of the thioxanthone derivatives include 2-isopropylthioxanthone, 2,4-dimethylthioxanthone, 2,4-diethylthioxanthone, 2-chlorothioxanthone, 2,4-diisopropylthioxanthone, and 4-isopropylthioxanthone.

Examples of the oxime ester compounds include 2-(O-benzoyloxime)-1-[4-(phenylthio)phenyl]-1,2-butanedione, 2-(O-benzoyloxime) 1-[4-(phenylthio)phenyl]-1,2-pentanedione, 2-(O-benzoyloxime)-1-[4-(phenylthio)phenyl]-1,2-hexanedione, 2-(O-benzoyloxime)-1-[4-(phenylthio)phenyl]-1,2-heptanedione, 2-(O-benzoyloxime)-1-[4-2-(O-benzoyloxime)-1-[4-(phenylthio)phenyl]-1,2-octanedione, 2-(O-benzoyloxime)-1-[4-(methylphenylthio)phenyl]-1,2-butanedione, (ethylphenylthio)phenyl]-1,2-butanedione, 2-(O-benzoyloxime)-1-[4-(butylphenylthio)phenyl]-1,2-butanedione, 1-(O-acetyloxime)-1-[9-ethyl-6-(2-methylbenzoyl)-9H-carbazol-3-yl]ethanone, 1-(O-acetyloxime)-1-[9-methyl-6-(2-methylbenzoyl)-9H-carbazol-3-yl]ethanone, 1-(O-acetyloxime)-1-[9-propyl-6-(2-methylbenzoyl)-9H-carbazol-3-yl]ethanone, 1-(O-acetyloxime)-1-[9-ethyl-6-(2-ethylbenzoyl)-9H-carbazol-3-yl]ethanone, 1-(O-acetyloxime)-1-[9-ethyl-6-(2-butylbenzoyl)-9H-carbazol-3-yl]ethanone, 2-(benzoyloxyimino)-1-[4-(phenylthio)phenyl]-1-octanone, and 2-(acetoxyimino)-4-(4-chlorophenylthio)-1-[9-ethyl-6-(2-methylbenzoyl)-9H-carbazol-3-yl]-1-butanone.

Examples of the benzoin derivatives include benzoin, benzoin methyl ether, benzoin ethyl ether, and benzoin isopropyl ether.

Examples of the acetophenone derivatives include acetophenone, 2,2-dimethoxy-2-phenylacetophenone, 2,2-diethoxy-2-phenylacetophenone, and 1,1-dichloroacetophenone.

Examples of the α-aminoacetophenone derivatives include 2-methyl-1-[4-(methylthio)phenyl]-2-morpholinopropan-1-one, 2-benzyl-2-dimethylamino-1-(4-morpholinophenyl)-butan-1-one, 2-(dimethylamino)-2-[(4-methylphenyl)methyl]-1-[4-(4-morpholinyl)phenyl]-1-butanone, and N,N-dimethylaminoacetophenone.

Examples of the hydroxyacetophenone derivatives include 2-hydroxy-1-(4-(4-(2-hydroxy-2-methylpropionyl)benzyl)phenyl)-2-methylpropan-1-one.

Examples of the anthraquinone derivatives include 2-methylanthraquinone, 2-ethylanthraquinone, 2-t-butylanthraquinone, and 1-chloroanthraquinone.

Examples of the acylphosphine oxide compounds include 2,4,6-trimethylbenzoyl diphenylphosphine oxide, (2,4,6-trimethylbenzoyl)ethoxyphenylphosphine oxide, bis(2,4,6-trimethylbenzoyl)-phenylphosphine oxide, and bis(2,6-dimethoxybenzoyl)-2,4,4-trimethyl-pentylphosphine oxide.

Examples of the titanocene compounds include di(cyclopentadienyl)-bis[2,6-difluoro-3-(2-(1H-pyrrol-1-yl)ethyl)phenyl]titanium, di(cyclopentadienyl)-bis[2,6-difluoro-3-(3-(1H-pyrrol-1-yl)propyl)phenyl]titanium, di(cyclopentadienyl)-bis[2,6-difluoro-3-((1H-pyrrol-1-yl)methyl)phenyl]titanium, bis(methylcyclopentadienyl)-bis[2,6-difluoro-3-((1H-pyrrol-1-yl)methyl)phenyl]titanium, di(cyclopentadienyl)-bis[2,6-difluoro-3-((2,5-dimethyl-1H-pyrrol-1-yl)methyl)phenyl]titanium, di(cyclopentadienyl)-bis[2,6-difluoro-3-((2-isopropyl-5-methyl-1H-pyrrol-1,6-yl)methyl)phenyl]titanium, di(cyclopentadienyl)-bis[2,6-difluoro-3-((2-(2-methoxyethyl)-5-methyl-1H-pyrrol-1-yl)methyl)phenyl]titanium, di(cyclopentadienyl)-bis[2,6-difluoro-3-((3-trimethylsilyl-2,5-dimethyl-1H-pyrrol-1-yl)methyl)phenyl]titanium, di(cyclopentadienyl)-bis[2,6-difluoro-3-((2,5-dimethyl-3-(bis(2-methoxyethyl)aminomethyl)-1H-pyrrol-1-yl)methyl)phenyl]titanium, di(cyclopentadienyl)-bis[2,6-difluoro-3-((2,5-bis(morpholinomethyl)-1H-pyrrol-1-yl)methyl)phenyl]titanium, di(cyclopentadienyl)-bis[2,6-difluoro-3-((2,5-dimethyl-3-(1,3-dioxolan-2-yl)-1H-pyrrol-1-yl)methyl)phenyl]titanium, di(cyclopentadienyl)-bis[2,6-difluoro-4-((2,5-dimethyl-1H-pyrrol-1-yl)methyl)phenyl]titanium, di(cyclopentadienyl)-bis[2,6-difluoro-3-methyl-4-(2-(1H-pyrrol-1-yl)ethyl)phenyl]titanium, di(cyclopentadienyl)-bis[2,6-difluoro-3-((2,3,4,5-tetramethyl-1H-pyrrol-1-yl)methyl)phenyl]titanium, di(cyclopentadienyl)-bis[2,3,5,6-tetrafluoro-4-(3-(1H-pyrrol-1-yl)propyl)phenyl]titanium, di(cyclopentadienyl)-bis[2,6-difluoro-3-(2-(1H-pyrrol-1-yl)propyl)phenyl]titanium, di(cyclopentadienyl)-bis[2,6-difluoro-3-(1-methyl-2-(1H-pyrrol-1-yl)ethyl)phenyl]titanium, di(cyclopentadienyl)-bis[2,6-difluoro-3-(3-(2-isoindol-2-yl)propyl)phenyl]titanium, di(cyclopentadienyl)-bis[2,6-difluoro-3-(2-(4,5,6,7-tetrahydro-isoindol-2-yl)ethyl)phenyl]titanium, di(cyclopentadienyl)-bis[2,6-difluoro-3-(6-(9-carbazol-9-yl)hexyl)phenyl]titanium, di(cyclopentadienyl)-bis[2,6-difluoro-3-(3-(2,3,4,5,6,7,8,9-octahydro-1-carbazol-9-yl)propyl)phenyl]titanium, di(cyclopentadienyl)-bis[2,6-difluoro-3-(3-(4,5,6,7-tetrahydro-2-methyl-1-indol-1-yl)propyl)phenyl]titanium, di(cyclopentadienyl)-bis[2,6-difluoro-3-((acetylamino)methyl)phenyl]titanium, di(cyclopentadienyl)-bis[2,6-difluoro-3-(2-(propionylamino)ethyl)phenyl]titanium, di(cyclopentadienyl)-bis[2,6-difluoro-3-(3-(acetylamino) propyl)phenyl]titanium, di(cyclopentadienyl)-bis[2,6-difluoro-3-(4-(pivaloylamino)butyl)phenyl]titanium, di(cyclopentadienyl)-bis[2,6-difluoro-3-(2-(2,2-dimethylpentanoylamino)ethyl)phenyl]titanium, di(cyclopentadienyl)-bis[2,6-difluoro-3-(3-(benzoylamino) propyl)phenyl]titanium, di(cyclopentadienyl)-bis[2,6-difluoro-3-((2,2-dimethylpentanoylamino)methyl)phenyl]titanium, di(cyclopentadienyl)-bis[2,6-difluoro-3-(2-(2,2-dimethyl-3-chloropropanoylamino)ethyl)phenyl]titanium, di(cyclopentadienyl)-bis[2,6-difluoro-3-((2,2-dimethyl-3-ethoxypropanoylamino)methyl)phenyl]titanium, di(cyclopentadienyl)-bis[2,6-difluoro-3-(2-(lauroylamino)ethyl)phenyl]titanium, di(cyclopentadienyl)-bis[2,6-difluoro-3-(2-(N-allylmethylsulfonylamino)ethyl)phenyl]titanium, di(cyclopentadienyl)-bis[2,6-difluoro-3-(3-(N-isobutylphenylsulfonylamino) propyl)phenyl]titanium, di(cyclopentadienyl)-bis[2,6-difluoro-3-((methylsulfonylamino)methyl)phenyl]titanium, di(cyclopentadienyl)-bis[2,6-difluoro-3-(3-(ethylsulfonylamino) propyl)phenyl]titanium, di(cyclopentadienyl)-bis[2,6-difluoro-3-(2-(butylsulfonylamino)ethyl)phenyl]titanium, di(cyclopentadienyl)-bis[2,6-difluoro-3-(4-(trisulfonylamino) propyl)phenyl]titanium, and bis(η⁵-2,4-cyclopentadiene-1-yl)-bis(2,6-difluoro-3-(1H-pyrrol-1-yl)phenyl) titanium.

The photopolymerization initiator preferably contains an acylphosphine oxide compound and a titanocene compound. When the photopolymerization initiator contains both an acylphosphine oxide compound and a titanocene compound, the resolution tends to be stable.

When the photopolymerization initiator contains an acylphosphine oxide compound and a titanocene compound, the mass ratio of the content of the acylphosphine oxide compound to the content of the titanocene compound (acylphosphine oxide compound/titanocene compound) may be, for example, 100 to 180, preferably 110 to 150, more preferably 120 to 140. When this mass ratio is in the above-described range, the resolution tends to be stable.

The content of the photopolymerization initiator in the curable resin composition may be, for example, 1 part by mass to 30 parts by mass, preferably 5 parts by mass to 25 parts by mass, more preferably 8 parts by mass to 20 parts by mass, still more preferably 10 parts by mass to 15 parts by mass, based on 100 parts by mass of the solid content of the alkali-soluble resin.

### Inorganic Filler

The curable resin composition may contain an inorganic filler.

The inorganic filler has a volume-average particle size of preferably 0.1 μm or less, more preferably 80 nm or less, still more preferably 70 nm or less, particularly preferably 60 nm or less, or 55 nm or less. When the volume-average particle size of the inorganic filler is equal to or less than the above-described upper limit, the scattered light of the inorganic filler is further reduced during exposure, so that the thin-film resolution tends to be further improved. Meanwhile, when the volume-average particle size of the inorganic filler is equal to or less than the above-described upper limit, since the transmittance at a wavelength of 405 nm is increased, the deep curing property is improved, so that the thick-film resolution tends to be improved. The volume-average particle size of the inorganic filler may be, for example, 10 nm to 0.1 μm, preferably 20 nm to 80 nm, more preferably 30 nm to 70 nm, still more preferably 40 nm to 60 nm, or 45 nm to 55 nm.

The inorganic filler may further contain a second inorganic filler having a volume-average particle size of more than 0.1 μm in addition to a first inorganic filler having a volume-average particle size of 0.1 μm or less. The volume-average particle size of the second inorganic filler may be, for example, more than 0.1 μm but 0.8 μm or less, preferably 0.15 μm to 0.6 μm, more preferably 0.2 μm to 0.4 μm.

When the inorganic filler contains the first inorganic filler and the second inorganic filler, the content percentage of the first inorganic filler in the inorganic filler, calculated on a solid content basis, is preferably 70% by mass to 100% by mass based on the total solid content of the inorganic filler, and may be more preferably 75% by mass to 100% by mass, still more preferably 80% by mass to 100% by mass, particularly preferably 90% by mass to 100% by mass, 95% by mass to 100% by mass, or 98% by mass to 100% by mass, or may be substantially 100% by mass. When the content percentage of the first inorganic filler in the inorganic filler is in the above-described range, the scattered light of the inorganic filler is further reduced during exposure, so that the thin-film resolution tends to be further improved.

The volume-average particle size of the inorganic filler refers to a value of the volume-average particle size (D50) that includes not only the particle size of primary particles but also the particle size of secondary particles (aggregates), and is a D50 value measured by a laser diffraction method. The volume-average particle size (D50) is a particle size corresponding to a cumulative of 50% from the small diameter side in a volume-based cumulative particle size distribution measured using a laser diffraction-type particle size distribution analyzer. Examples of a measurement device based on a laser diffraction method include MICROTRAC MT3300EX II manufactured by MicrotracBEL Corp. Further, the volume-average particle size of the inorganic filler contained in the curable resin composition refers to a value measured as described above for the inorganic filler prior to the preparation (pre-stirring, kneading) of the curable resin composition.

Examples of the inorganic filler include silicon oxide, barium sulfate, talc, Neuburg siliceous earth, aluminum hydroxide, glass powder, clay, magnesium carbonate, calcium carbonate, natural mica, synthetic mica, barium titanate, iron oxide, non-fibrous glass, hydrotalcite, mineral wool, aluminum silicate, calcium silicate, zinc white, and alumina. These inorganic fillers may be used singly, or in combination of two or more kinds thereof.

From the standpoint of resolution and low thermal expansion, the inorganic filler preferably contains a silicon oxide. The silicon oxide, which is a compound represented by SiOₓ (0<x≤2), may be preferably silicon dioxide, such as silica or crystalline silica.

The content percentage of the silicon oxide in the inorganic filler, calculated on a solid content basis, is preferably 70% by mass to 100% by mass, and may be more preferably 75% by mass to 100% by mass, still more preferably 80% by mass to 100% by mass, particularly preferably 90% by mass to 100% by mass, 95% by mass to 100% by mass, or 98% by mass to 100% by mass, based on the total solid content of the inorganic filler. When the content percentage of the silicon oxide in the inorganic filler is in the above-described range, the scattered light of the inorganic filler is further reduced during exposure, so that the thin-film resolution tends to be further improved.

The content percentage of an inorganic filler other than the silicon oxide in the inorganic filler, calculated on a solid content basis, is preferably 0% by mass or more but less than 30% by mass, and may be more preferably less than 25% by mass, still more preferably less than 20% by mass, particularly preferably less than 10% by mass, less than 5% by mass, or less than 2% by mass, based on the total solid content of the inorganic filler. When the content percentage of an inorganic filler other than the silicon oxide, such as barium sulfate, is in the above-described range, the scattered light of the inorganic filler tends to be further reduced.

The content of the inorganic filler in the curable resin composition may be, for example, 20 parts by mass to 100 parts by mass, preferably 30 parts by mass to 90 parts by mass, more preferably 40 parts by mass to 80 parts by mass, still more preferably 45 parts by mass to 75 parts by mass, particularly preferably 50 parts by mass to 70 parts by mass, based on 100 parts by mass of the solid content of the alkali-soluble resin.

The content percentage of the inorganic filler in the curable resin composition, calculated on a solid content basis, may be, for example, 10% by mass to 50% by mass, preferably 15% by mass to 40% by mass, more preferably 18% by mass to 35% by mass, still more preferably 20% by mass to 30% by mass, particularly preferably 20% by mass to 25% by mass, based on the total solid content of the curable resin composition. When the content percentage of the inorganic filler is in the above-described range, a good balance of the resolution and the mechanical properties tends to be obtained.

### Colorant

The curable resin composition may contain a colorant. As the colorant, any commonly used and known colorant of red, blue, green, yellow, white, black, or the like may be used, and the colorant may be any of a pigment, a dye, and a coloring matter. In the curable resin composition, the colorant may be contained singly, or in combination of two or more kinds thereof.

Examples of the red colorant include monoazo-type, disazo-type, azo lake-type, benzimidazolone-type, perylene-type, diketopyrrolopyrrole-type, condensed azo-type, anthraquinone-type, and quinacridone-type colorants. Examples of the blue colorant include phthalocyanine-type and anthraquinone-type colorants and, as a pigment-type colorant, any compound classified as pigment may be used. In addition to these colorants, a metal-substituted or unsubstituted phthalocyanine compound may be used as well. Similarly, examples of the green colorant include phthalocyanine-type, anthraquinone-type, and perylene-type colorants. In addition to these colorants, a metal-substituted or unsubstituted phthalocyanine compound may be used as well. Examples of the yellow colorant include monoazo-type, disazo-type, condensed azo-type, benzimidazolone-type, isoindolinone-type, and anthraquinone-type colorants. Examples of the white colorant include rutile-type and anatase-type titanium oxide. Examples of the black colorant include carbon black-type, graphite-type, and iron oxide-type, titanium black, anthraquinone-type, cobalt oxide-type, copper oxide-type, manganese-type, antimony oxide-type, nickel oxide-type, perylene-type, and aniline-type colorants, as well as molybdenum sulfide and bismuth sulfide. In addition to the above, for the purpose of adjusting the color tone, colorants of violet, orange, brown, and the like may be added as well.

Specific examples of the colorant contained in the curable resin composition include those colorants that are assigned with the following Color Index numbers (C.I.; issued by The Society of Dyers and Colourists), such as PIGMENT BLUE 15, 15:1, 15:2, 15:3, 15:4, 15:6, 16, and 60; SOLVENT BLUE 35, 63, 68, 70, 83, 87, 94, 97, 122, 136, 67, and 70; PIGMENT GREEN 7, 36, 3, 5, 20, and 28; SOLVENT YELLOW 163; PIGMENT YELLOW 24, 108, 193, 147, 199, 202, 110, 109, 139, 179, 185, 93, 94, 95, 128, 155, 166, 180, 120, 151, 154, 156, 175, 181, 1, 2, 3, 4, 5, 6, 9, 10, 12, 61, 62, 62:1, 65, 73, 74, 75, 97, 100, 104, 105, 111, 116, 167, 168, 169, 182, 183, 12, 13, 14, 16, 17, 55, 63, 81, 83, 87, 126, 127, 152, 170, 172, 174, 176, 188, and 198; PIGMENT ORANGE 1, 5, 13, 14, 16, 17, 24, 34, 36, 38, 40, 43, 46, 49, 51, 61, 63, 64, 71, and 73; PIGMENT RED 1, 2, 3, 4, 5, 6, 8, 9, 12, 14, 15, 16, 17, 21, 22, 23, 31, 32, 112, 114, 146, 147, 151, 170, 184, 187, 188, 193, 210, 245, 253, 258, 266, 267, 268, 269, 37, 38, 41, 48:1, 48:2, 48:3, 48:4, 49:1, 49:2, 50:1, 52:1, 52:2, 53:1, 53:2, 57:1, 58:4, 63:1, 63:2, 64:1, 68, 171, 175, 176, 185, 208, 123, 149, 166, 178, 179, 190, 194, 224, 254, 255, 264, 270, 272, 220, 144, 166, 214, 220, 221, 242, 168, 177, 216, 122, 202, 206, 207, and 209; SOLVENT RED 135, 179, 149, 150, 52, and 207; PIGMENT VIOLET 19, 23, 29, 32, 36, 38, and 42; SOLVENT VIOLET 13 and 36; PIGMENT BROWN 23 and 25; and PIGMENT BLACK 1 and 7.

The type of the colorant contained in the curable resin composition is not particularly limited as long as the transmittance of the cured product at a wavelength of 405 nm and at a wavelength of 650 nm can be adjusted in the above-described respective ranges, and the colorant may be any of a red colorant, a blue colorant, a green colorant, a yellow colorant, a white colorant, and a black colorant.

From the standpoint of the ease of adjusting the transmittance of the 10 μm-thick cured product at a wavelength of 405 nm to be in the above-described range and the ease of improving the deep curing property and the thick-film resolution, the colorant contained in the curable resin composition preferably does not contain any black colorant, i.e., the colorant is preferably at least one selected from the group consisting of red colorants, blue colorants, green colorants, yellow colorants, and white colorants, more preferably at least one selected from the group consisting of blue colorants and yellow colorants.

From the standpoint of the ease of adjusting the transmittance of the 10 μm-thick cured product at a wavelength of 650 nm to be in the above-described range and the ease of improving the thin-film resolution and the masking property, the colorant contained in the curable resin composition preferably does not contain any white colorant, i.e., the colorant is preferably at least one selected from the group consisting of red colorants, blue colorants, green colorants, yellow colorants, and black colorants, more preferably at least one selected from the group consisting of blue colorants and yellow colorants.

The colorant contained in the curable resin composition preferably contains at least one blue colorant and at least one yellow colorant.

The content of the colorant in the curable resin composition may be, for example, 1 part by mass to 10 parts by mass, preferably 1.5 parts by mass to 5 parts by mass, more preferably 1.7 parts by mass to 2.7 parts by mass, based on 100 parts by mass of the solid content of the alkali-soluble resin.

The content percentage of the colorant in the curable resin composition, calculated on a solid content basis, may be preferably 0.70% by mass to 1.10% by mass, more preferably 0.75% by mass to 1.03% by mass, still more preferably 0.80% by mass to 0.97% by mass, particularly preferably 0.85% by mass to 0.95% by mass, 0.85% by mass to 0.93% by mass, or 0.86% by mass to 0.90% by mass, based on the total solid content of the curable resin composition. When the content percentage of the colorant in the curable resin composition is equal to or more than the above-described lower limit, reflected light and scattered light may be sufficiently absorbed during exposure, and halation may thereby be further inhibited; therefore, the thin-film resolution may be further improved. Meanwhile, when the content percentage of the colorant in the curable resin composition is equal to or less than the above-described upper limit, since a sufficient amount of light may reach a deep part during exposure, the deep curing property and the thick-film resolution may be further improved.

When the colorant contains a blue colorant and a yellow colorant, the mass ratio of the content of the blue colorant to the content of the yellow colorant (blue colorant/yellow colorant), each content being calculated on a solid content basis, may be preferably 1.0 to 2.0, more preferably 1.1 to 1.8, still more preferably 1.2 to 1.7, or 1.3 to 1.5. When this mass ratio is in the above-described range, a good balance of the masking property and the resolution tends to be obtained.

The mass ratio of the content of the colorant to the content of the inorganic filler in the curable resin composition (colorant/inorganic filler), each content being calculated on a solid content basis, may be preferably 0.015 to 0.05, more preferably 0.02 to 0.045, still more preferably 0.03 to 0.04.

### Photopolymerizable Monomer

If necessary, the curable resin composition may further contain a photopolymerizable monomer. The photopolymerizable monomer may be used singly, or in combination of two or more kinds thereof.

The photopolymerizable monomer may be, for example, a (meth)acrylate-based monomer or an allyl compound.

Examples of the (meth)acrylate-based monomer include (meth)acrylamides, (meth)acrylic acid esters, hydroxyalkyl (meth)acrylates, alkoxyalkylene mono(meth)acrylates, alkylene glycol poly(meth)acrylates, alkylene polyol poly(meth)acrylates, polyoxyalkylene glycol poly(meth)acrylates, and isocyanurate-type poly(meth)acrylates.

Examples of the (meth)acrylamides include (meth)acrylamide, N-hydroxymethyl (meth)acrylamide, N-methoxymethyl (meth)acrylamide, N-ethoxymethyl (meth)acrylamide, and N-butoxymethyl (meth)acrylamide. Examples of the (meth)acrylic acid esters include 2-ethylhexyl (meth)acrylate, lauryl (meth)acrylate, tetrahydrofurfuryl (meth)acrylate, isobornyl (meth)acrylate, phenyl (meth)acrylate, and phenoxyethyl (meth)acrylate. Examples of the hydroxyalkyl (meth)acrylates include hydroxyethyl (meth)acrylate, hydroxypropyl (meth)acrylate, and pentaerythritol tri(meth)acrylate. Examples of the alkoxyalkylene mono(meth)acrylates include methoxyethyl (meth)acrylate and ethoxyethyl (meth)acrylate. Examples of the alkylene glycol poly(meth)acrylates include ethylene glycol di(meth)acrylate and butanediol di(meth)acrylate. Examples of the alkylene polyol poly(meth)acrylates include neopentyl glycol di(meth)acrylate, 1,6-hexanediol di(meth)acrylate, trimethylolpropane tri(meth)acrylate, pentaerythritol tetra(meth)acrylate, and dipentaerythritol hexa(meth)acrylate. Examples of the polyoxyalkylene glycol poly(meth)acrylates include diethylene glycol di(meth)acrylate, triethylene glycol di(meth)acrylate, ethoxylated trimethylolpropane triacrylate, and propoxylated trimethylolpropane tri(meth)acrylate. Examples of the isocyanurate-type poly(meth)acrylates include tris[(meth)acryloxyethyl]isocyanurate.

Examples of the (meth)acrylate-based monomer preferably include poly(meth)acrylates (polyfunctional (meth)acrylates), such as alkylene glycol poly(meth)acrylates, alkylene polyol poly(meth)acrylates, polyoxyalkylene glycol poly(meth)acrylates, and isocyanurate-type poly(meth)acrylates, and alkylene polyol poly(meth)acrylates are more preferred. From the standpoint of improving the crosslink density and the mechanical properties of the resulting curable resin composition, the poly(meth)acrylates are preferably, for example, tetrafunctional or higher-functional (meth)acrylates.

Examples of the allyl compound include triallyl isocyanurate. diallyl phthalate, and diallyl isophthalate.

The content of the photopolymerizable monomer in the curable resin composition may be, for example, 10 parts by mass to 30 parts by mass, preferably 12 parts by mass to 25 parts by mass, more preferably 15 parts by mass to 20 parts by mass, based on 100 parts by mass of the solid content of the alkali-soluble resin.

### Heat-Curing Catalyst

The curable resin composition may contain a thermal curing catalyst.

Examples of the thermal curing catalyst include: imidazole derivatives, such as imidazole, 2-methylimidazole, 2-ethylimidazole, 2-ethyl-4-methylimidazole, 2-phenylimidazole, 4-phenylimidazole, 1-cyanoethyl-2-phenylimidazole and 1-(2-cyanoethyl)-2-ethyl-4-methylimidazole; amine compounds, such as dicyandiamide, benzyldimethylamine, 4-(dimethylamino)-N,N-dimethylbenzylamine, 4-methoxy-N,N-dimethylbenzylamine, and 4-methyl-N,N-dimethylbenzylamine; hydrazine compounds, such as adipic acid dihydrazide and sebacic acid dihydrazide; phosphorus compounds, such as triphenyl phosphine; and s-triazine derivatives, such as guanamine, acetoguanamine, benzoguanamine, melamine, 2,4-diamino-6-methacryloyloxyethyl-s-triazine, 2-vinyl-2,4-diamino-s-triazine, 2-vinyl-4,6-diamino-s-triazine isocyanuric acid adduct, and 2,4-diamino-6-methacryloyloxyethyl-s-triazine isocyanuric acid adduct. Examples of commercially available thermal curing catalysts include: 2MZ-A, 2MZ-OK, 2PHZ, 2P4BHZ, and 2P4 MHZ, which are manufactured by Shikoku Chemicals Corporation (all of which are trade names of imidazole compounds); and U-CAT (registered trademark) 3503N and U-CAT 3502T (both of which are trade names of blocked isocyanate compounds of dimethylamine), as well as DBU, DBN, U-CAT SA102 and U-CAT 5002 (all of which are either a bicyclic amidine compound or a salt thereof), which are manufactured by San-Apro Ltd. These thermal curing catalysts may be used singly, or in combination of two or more kinds thereof.

The content of the thermal curing catalyst in the curable resin composition may be, for example, 1 part by mass to 20 parts by mass, preferably 3 parts by mass to 15 parts by mass, more preferably 5 parts by mass to 10 parts by mass, based on 100 parts by mass of the solid content of the alkali-soluble resin.

The content percentage of the thermal curing catalyst, calculated on a solid content basis, may be, for example, 5% by mass to 30% by mass, preferably 10% by mass to 25% by mass, more preferably 15% by mass to 20% by mass, based on the solid content of the thermosetting resin.

### Organic Solvent

The curable resin composition may also contain an organic solvent for the purposes of, for example, adjusting the viscosity at the time of preparing a resin composition and applying the resin composition to a base material.

Examples of the organic solvent include: ketones, such as methyl ethyl ketone and cyclohexanone; aromatic hydrocarbons, such as toluene, xylene, and tetramethyl benzene; glycol ethers, such as cellosolve, methyl cellosolve, butyl cellosolve, carbitol, methyl carbitol, butyl carbitol, propylene glycol monomethyl ether, dipropylene glycol monomethyl ether, dipropylene glycol diethyl ether, diethylene glycol monomethyl ether acetate, and tripropylene glycol monomethyl ether; esters, such as ethyl acetate, butyl acetate, butyl lactate, cellosolve acetate, butylcellosolve acetate, carbitol acetate, butylcarbitol acetate, propylene glycol monomethyl ether acetate, dipropylene glycol monomethyl ether acetate, and propylene carbonate; aliphatic hydrocarbons, such as octane and decane; and petroleum-based solvents, such as petroleum ether, petroleum naphtha, and solvent naphtha. These organic solvents may be used singly, or in combination of two or more kinds thereof.

When the curable resin composition contains an organic solvent, the content of the organic solvent is not particularly limited, and may be set as appropriate in accordance with the desired viscosity and the like.

### Other Additives

The curable resin composition may further contain other additives that are known and commonly used in the field of electronic materials. Examples of such other additives include polymerization inhibitors, UV absorbers, silane coupling agents, plasticizers, flame retardants, antistatic agents, aging inhibitors, antibacterial/antifungal agents, antifoaming agents, leveling agents, thickeners, adhesion promoters, thixotropic agents, photoinitiator aids, sensitizers, thermoplastic resins, organic fillers, mold release agents, surface treatment agents, dispersants, dispersion aids, surface modifiers, stabilizers, and phosphors.

A total content of the other additives in the curable resin composition may be, for example, 0.1 parts by mass to 10 parts by mass, preferably 0.5 parts by mass to 5 parts by mass, more preferably 1 part by mass to 3 parts by mass, based on 100 parts by mass of the solid content of the alkali-soluble resin.

The curable resin composition according to one aspect of the present disclosure may form a cured film that is excellent in masking property, thin-film resolution, and thick-film resolution on a substrate surface having a copper circuit formed thereon, and this cured film may be suitably used as a solder resist.

The curable resin composition may be used in the form of a dry film, or may be used as a liquid. When used as a liquid, the curable resin component may be of a one-component type, or a two or more-component type.

The curable resin composition may be produced by any known method. For example, the curable resin composition may be prepared by blending the components to be contained therein, and stirring and kneading the resultant using a stirrer, a kneader, and the like.

### Dry Film

The curable resin composition may be provided in the form of a dry film including: a first film (e.g., a support (carrier) film); and a resin layer formed on the first film, the resin layer being a dry coating film of the curable resin composition. In other words, the present disclosure may encompass, as one aspect, a dry film including: a first film; and a resin layer laminated on the first film, the resin layer being a dry coating film of the curable resin composition.

In the preparation of the dry film, the curable resin composition may be diluted with an organic solvent to adjust the viscosity to an appropriate level, applied onto the first film to a uniform thickness using a comma coater, a blade coater, a lip coater, a rod coater, a squeeze coater, a reverse coater, a transfer roll coater, a gravure coater, a spray coater, or the like, and then dried, usually at a temperature of 50° C. to 130° C. for 1 minute to 30 minutes, to obtain a dry coating film. The thickness of the coating film (the thickness of the resin layer) is not particularly limited and, for example, the film thickness after the drying may be selected as appropriate in a range of 1 μm to 50 μm, preferably 3 μm to 15 μm.

The first film refers to a film that is adhered to at least the resin layer when the dry film is laminated and integrally molded by heating or the like such that the resin layer side of the dry film is in contact with a base material such as a substrate. As the first film, any known such film may be used without particular limitation and, for example, a film made of a thermoplastic resin, such as a polyester film of polyethylene terephthalate, polyethylene naphthalate, or the like, a polyimide film, a polyamideimide film, a polypropylene film, or a polystyrene film, may be suitably used. Thereamong, a polyester film is preferred from the standpoint of heat resistance, mechanical strength, ease of handling, and the like. Further, a laminate of these films may be used as the first film.

From the standpoint of improving the mechanical strength, the above-described thermoplastic resin film is preferably a uniaxially or biaxially stretched film.

The thickness of the first film is not particularly limited and may be, for example, 10 μm to 150 μm, 15 μm to 100 μm, or 20 μm to 80 μm.

After the resin layer that is a dry coating film of the curable resin composition is formed on the first film, a peelable second film (e.g., a protective (cover) film) is preferably further laminated on the surface of the resin layer for the purpose of, for example, preventing dust adhesion to the surface of the resin layer. In other words, in one aspect, the dry film includes the first film, the resin layer, and the second film in this order. The second film refers to a film that is peeled off from the resin layer before lamination when the dry film is laminated and integrally molded by heating or the like such that the resin layer side of the dry film is in contact with a base material such as a substrate. As the peelable second film, for example, a polyethylene film, a polytetrafluoroethylene film, a polypropylene film, or a piece of surface-treated paper may be used, and the adhesive force between the resin layer and the second film only needs to be smaller than the adhesive force between the resin layer and the first film at the time of peeling off the second film.

The thickness of the second film is not particularly limited and may be, for example, 10 μm to 150 μm, 15 μm to 100 μm, or 20 μm to 80 μm.

In order to produce a cured film that may be used as a solder resist on a printed wiring board using the dry film, the second film is peeled off from the dry film, the thus exposed resin layer of the dry film is disposed on a base material having a circuit formed thereon, and the resin layer and the base material are attached using a laminator or the like to form the resin layer on the base material having a circuit formed thereon. Thereafter, the thus formed resin layer is exposed, developed, and heat-cured, whereby a cured film may be formed. The first film may be peeled off either before or after the exposure.

The resin layer in the dry film, when made into a 10 μm-thick test piece, exhibits a transmittance at a wavelength of 405 nm of, for example, 60% to 75%, preferably 63% to 70%, more preferably 66% or higher but lower than 70%, still more preferably 67% to 69%, or higher than 67% but lower than 69%. Further, the resin layer in the dry film, when made into a 10 μm-thick test piece, exhibits a transmittance at a wavelength of 650 nm of, for example, 45% to 62%, 45% to 61%, or 45% to 60%, preferably 49% to 60%, more preferably 50% to 60%, still more preferably 52% to 60%, 55% to 60%, or 58% to 60%. The transmittance of the resin layer in the dry film can be measured in the same manner as that of a cured product.

### Cured Product

The present disclosure may encompass a cured product as one aspect. The cured product is obtained by curing the above-described curable resin composition, or the resin layer of the above-described dry film. The production conditions, such as curing conditions, will be described below. The cured product is suitable as a solder resist of an electronic component for a printed wiring board or the like. The cured product, when made into a 10 μm-thick test piece, exhibits a transmittance at a wavelength of 405 nm of, for example, 60% to 75%, preferably 63% to 70%, more preferably 66% or higher but lower than 70%, still more preferably 67% to 69%, or higher than 67% but lower than 69%. Further, the cured product, when made into a 10 μm-thick test piece, exhibits a transmittance at a wavelength of 650 nm of, for example, 45% to 62%, 45% to 61%, or 45% to 60%, preferably 49% to 60%, more preferably 50% to 60%, still more preferably 52% to 60%, 55% to 60%, or 58% to 60%.

### Electronic Component

The present disclosure may encompass an electronic component including the cured product as one aspect. The term “electronic component” used herein refers to a component used in an electronic circuit, and examples thereof include printed wiring boards.

The substrate is preferably a substrate having a wiring circuit (a substrate on which a circuit pattern has been formed). Examples of the substrate having a wiring circuit include: printed wiring boards and flexible printed wiring boards on which a circuit is formed with copper or the like in advance; copper-clad laminated boards using paper phenol, paper epoxy, glass cloth epoxy, glass polyimide, glass cloth/nonwoven fabric epoxy, glass cloth/paper epoxy, synthetic fiber epoxy, fluorine resin-polyethylene-polyphenylene ether, polyphenylene oxide-cyanate, or the like; metal substrates; glass substrates; ceramic substrates; and wafer boards. In the present disclosure, films such as a polyimide film, a polyethylene terephthalate film, and a polyethylene naphthalate film may also be used as the substrate.

As a method of producing a printed wiring board, for example, the curable resin composition is adjusted with an organic solvent to have a viscosity suitable for an application method if necessary, and applied onto a base material by a method such as dip coating, flow coating, roll coating, bar coating, screen printing, or curtain coating, after which the organic solvent contained in the composition is dried by evaporation (pre-dried) at a temperature of 60° C. to 100° C. for 15 minutes to 90 minutes to form a tack-free resin layer. In the case of the dry film, using a laminator or the like, the dry film is attached to a base material such that the resin layer comes into contact with the base material, whereby a resin layer is formed on the base material.

The drying by evaporation, which is performed after applying the curable resin composition onto the base material, may be performed using a hot air circulation-type drying oven, an IR oven, a hot plate, a convection oven, or the like. Examples of the hot air circulation-type drying oven include DF610 manufactured by Yamato Scientific Co., Ltd.

The dry film is preferably attached to the base material using a vacuum laminator or the like under pressure with heating. By using such a vacuum laminator, when a substrate having a circuit formed thereon is used, the resin layer of the dry film tightly adheres to the circuit substrate even with irregularities on the surface of the circuit substrate; therefore, entrapment of air bubbles does not occur, and the fillability of the recesses on the substrate surface is improved. The pressure condition is preferably about 0.1 MPa to 2.0 MPa, and the heating condition is preferably 40° C. to 120° C.

After the formation of the resin layer on the base material, the resin layer is selectively exposed to an actinic radiation through a photomask on which a prescribed pattern is formed, and an unexposed portion is developed with a dilute alkaline aqueous solution to form a patterned cured product on the base material. In the case of the dry film, after exposure, the first film is peeled off from the dry film, and this is followed by development to form a patterned cured product on the base material. It is noted here that, as long as the properties are not deteriorated, the first film may be peeled off from the dry film before the exposure, and the exposed resin layer may be subjected to exposure and development.

An exposure apparatus used for the actinic radiation irradiation may be any apparatus that is equipped with a high-pressure mercury lamp, an ultrahigh-pressure mercury lamp, a metal halide lamp, a mercury short arc lamp, or the like, and irradiates ultraviolet rays having a maximum wavelength of 350 nm to 450 nm. Further, a direct drawing apparatus (e.g., a laser direct imaging apparatus that directly draws an image with a laser based on CAD data transmitted from a computer) may be used as well. As a lamp light source or a laser light source of the direct drawing apparatus, a light source having a maximum wavelength of 350 nm to 450 nm may be used. The exposure dose for the image formation varies depending on the thickness and the size of the cured product; however, it is preferably 10 mJ/cm² to 1,000 mJ/cm², more preferably 20 mJ/cm² to 800 mJ/cm².

As a development method, a dipping method, a shower method, a spray method, a brush method, or the like may be employed and, as a developer, an alkaline aqueous solution of potassium hydroxide, sodium hydroxide, sodium carbonate, potassium carbonate, sodium phosphate, sodium silicate, ammonia, amine, or the like may be used.

Further, by further performing actinic radiation irradiation and heat-curing treatment on the cured product, a cured product excellent in various properties, such as adhesion and hardness, may be formed. The actinic radiation irradiation may be performed under the condition of 500 mJ/cm² to 3,000 mJ/cm² and, as an apparatus, a UV conveyor equipped with a high-pressure mercury lamp, such as QRM-2082 manufactured by ORC Manufacturing Co., Ltd., may be used. As a heat-curing method, heat-curing is preferably performed at 140° C. to 200° C. for 30 minutes to 90 minutes. The heat-curing may be performed using a hot air circulation-type drying oven, an IR oven, a hot plate, a convection oven, or the like.

The present disclosure will now be described more concretely by way of Examples; however, the present disclosure is not limited to the below-described Examples. Unless otherwise specified, “part(s)” and “%” are based on mass.

### EXAMPLES

### Preparation Example 1: Preparation of Resin Solution 1 of Alkali-Soluble Resin

To an autoclave equipped with a thermometer, a device for nitrogen introduction and alkylene oxide introduction, and a stirring device, 119.4 parts by mass of a novolac-type cresol resin (trade name “SHONOL CRG951”, manufactured by Aica Kogyo Co., Ltd., OH equivalent: 119.4), 1.19 parts by mass of potassium hydroxide, and 119.4 parts by mass of toluene were added, and the inside of the system was purged with nitrogen while stirring, after which the temperature was raised by heating. Subsequently, 63.8 parts by mass of propylene oxide was slowly added dropwise, and the resultant was allowed to react for 16 hours at a temperature of 125° C. to 132° C. and a gauge pressure of 0 kg/cm² to 4.8 kg/cm². Then, the system was cooled to room temperature, and 1.56 parts by mass of 89% phosphoric acid was added to and mixed with the resulting reaction solution to neutralize potassium hydroxide, whereby a propylene oxide reaction solution of the novolac-type cresol resin, which had a non-volatile content (solid content) of 62.1% and a hydroxyl value of 182.2 g/eq., was obtained. In this reaction solution, an average of 1.08 mol of propylene oxide was added per 1 equivalent of phenolic hydroxy group.

Next, 293.0 parts by mass of the thus obtained propylene oxide reaction solution of the novolac-type cresol resin, 43.2 parts by mass of acrylic acid, 11.53 parts by mass of methanesulfonic acid, 0.18 parts by mass of methylhydroquinone and 252.9 parts by mass of toluene were added to a reactor equipped with a stirrer, a thermometer, and an air blowing tube and, while blowing air into the reactor at a rate of 10 ml/min, the added materials were allowed to react for 12 hours at 110° C. with stirring. Then, 12.6 parts by mass of water generated by the reaction was distilled off as an azeotropic mixture with toluene. Subsequently, the system was cooled to room temperature, and the thus obtained reaction solution was neutralized with 35.35 parts by mass of 15% aqueous sodium hydroxide solution and then washed with water. Thereafter, using an evaporator, toluene was distilled off while being replaced with 118.1 parts by mass of diethylene glycol monoethyl ether acetate, whereby a novolac-type acrylate resin solution was obtained. Next, 332.5 parts by mass of the thus obtained novolac-type acrylate resin solution and 1.22 parts by mass of triphenyl phosphine were added to a reactor equipped with a stirrer, a thermometer, and an air blowing tube and, while blowing air into the reactor at a rate of 10 ml/min and stirring the added materials, 60.8 parts by mass of tetrahydrophthalic anhydride was slowly added and allowed to react for 6 hours at 95° C. to 101° C. In this manner, a resin solution 1 of a carboxy group-containing photosensitive resin having a solid acid value of 88 mgKOH/g, a solid content of 71%, and a weight-average molecular weight of 2,000 was obtained.

### EXAMPLES AND COMPARATIVE EXAMPLES

### Preparation of Curable Resin Compositions

In accordance with the respective ratios shown in Table 1, materials were blended, pre-mixed using a stirrer, and then kneaded using a three-roll mill to prepare curable resin compositions. The values in the table are based on the solid content. Further, the unit in the table is parts by mass. The unit of the content percentage of each component is % by mass. In the table, “-” indicates that the component of interest was not added.

TABLE 1

| | | Example | | | | | | | Comparative Example | | | | | | |
|---|---|---|---|---|---|---|---|---|---|---|---|---|---|---|---|
| Component name | | 1 | 2 | 3 | 4 | 5 | 6 | 7 | 1 | 2 | 3 | 4 | 5 | 6 | 7 |
| (A) Alkali- | Resin | 100 | 100 | 100 | 100 | 100 | 100 | 100 | 100 | 100 | 100 | 100 | 100 | 100 | 100 |
| soluble | solution | | | | | | | | | | | | | | |
| resin | 1 | | | | | | | | | | | | | | |
| (B) Thermo | Epoxy | 46 | 46 | 46 | 46 | 46 | 46 | 46 | 48 | 46 | 46 | 46 | 46 | 46 | 46 |
| setting resin | resin | | | | | | | | | | | | | | |
| (C) Photopoly- | TPO-L | 13 | 13 | 13 | 13 | 13 | 13 | 13 | 13 | 13 | 13 | 13 | 13. | 13 | 13 |
| merization | JMT-784 | 0.1 | 0.1 | 0.1 | 0.1 | 0.1 | 0.1 | 0.1 | 0.1 | 0.1 | 0.1 | 0.1 | 0.1 | 0.1 | 0.1 |
| initiator | | | | | | | | | | | | | | | |
| (D) Colorant | Blue colorant | 1.25 | 1.25 | 1.25 | 1.5 | 1.25 | 1.25 | 1.8 | 1.9 | 1.25 | 0.7 | 1.5 | 1.25 | 0.65 | 0.65 |
| | Yellow | 0.9 | 0.9 | 0.9 | 0.9 | 1.0 | 0.7 | 0.9 | 0.9 | 1.7 | 0.9 | 0.0 | 0.9 | 0.45 | 0.45 |
| | colorant | | | | | | | | | | | | | | |
| (E) Inorganic | Silica 1 | 57 | — | 57 | 57 | 57 | 57 | 57 | 57 | 57 | 57 | 57 | — | 57 | — |
| filler | (D50: 50 nm) | | | | | | | | | | | | | | |
| | Silica 2 | — | 57 | — | — | — | — | — | — | — | — | — | — | — | — |
| | (D50: 70 nm) | | | | | | | | | | | | | | |
| | Silica 3 | — | — | — | — | — | — | — | — | — | — | — | 57 | — | 57 |
| | (D50: 0.8 μm) | | | | | | | | | | | | | | |
| | Barium sulfate | — | — | 18 | — | — | — | — | — | — | — | — | 18 | 18 | 18 |
| Photopoly- | DA-600 | 18 | 18 | 18 | 18 | 18 | 18 | 18 | 18 | 18 | 18 | 18 | 18 | 18 | 18 |
| merizable | | | | | | | | | | | | | | | |
| monomer | | | | | | | | | | | | | | | |
| thermal curing | Melamine | 7.2 | 7.2 | 7.2 | 7.2 | 7.2 | 7.2 | 7.2 | 7.2 | 7.2 | 7.2 | 7.2 | 7.2 | 7.2 | 7.2 |
| catalyst | Dicyan- | 1 | 1 | 1 | 1 | 1 | 1 | 1 | 1 | 1 | 1 | 1 | 1 | 1 | 1 |
| | diamide | | | | | | | | | | | | | | |
| Additive | Antifoaming | 1.5 | 1.5 | 1.5 | 1.5 | 1.5 | 1.5 | 1.5 | 1.5 | 1.5 | 1.5 | 1.5 | 1.5 | 1.5 | 1.5 |
| | agent | | | | | | | | | | | | | | |
| | Polymeriza- | 0.1 | 0.1 | 0.1 | 0.1 | 0.1 | 0.1 | 0.1 | 0.1 | 0.1 | 0.1 | 0.1 | 0.1 | 0.1 | 0.1 |
| | tion inhibitor | | | | | | | | | | | | | | |
| Content percentage of inorganic | | 23.2% | 23.2% | 28.4% | 23.1% | 23.2% | 23.2% | 23.1% | 23.1% | 23.1% | 23.2% | 23.2% | 28.4% | 28.5% | 28.5% |
| fillerin resin composition | | | | | | | | | | | | | | | |
| Content percentage of silica in | | 100% | 100% | 76% | 100% | 100% | 100% | 100% | 100% | 100% | 100% | 100% | 76% | 76% | 76% |
| inorganic filler | | | | | | | | | | | | | | | |
| Content percentage of colorant | | 0.87% | 0.87% | 0.81% | 0.97% | 0.91% | 0.79% | 1.09% | 1.13% | 1.20% | 0.65% | 0.61% | 0.81% | 0.42% | 0.42% |
| in resin composition | | | | | | | | | | | | | | | |
| Blue colorant/Yellow colorant | | 1.39 | 1.39 | 1.39 | 1.67 | 1.25 | 1.79 | 2.00 | 2.11 | 0.74 | 0.78 | — | 1.39 | 1.44 | 1.44 |
| Colorant/Inorganic filler | | 0.04 | 0.04 | 0.03 | 0.04 | 0.04 | 0.03 | 0.05 | 0.05 | 0.05 | 0.03 | 0.03 | 0.03 | 0.01 | 0.01 |
| Transmittance at a wavelength | | 68% | 65% | 68% | 65% | 65% | 69% | 63% | 60% | 57% | 70% | 76% | 59% | 71% | 69% |
| of 405 nm | | | | | | | | | | | | | | | |
| Transmittance at a wavelength | | 60% | 58% | 60% | 53% | 58% | 60% | 48% | 44% | 53% | 70% | 58% | 52% | 74% | 63% |
| of 650 nm | | | | | | | | | | | | | | | |
| Evaluation results | Masking | A | A | A | A | A | B | A | A | A | C | A | A | C | C |
| | property | | | | | | | | | | | | | | |
| | Thin-film | A | A | B | A | A | B | A | A | A | B | C | B | B | C |
| | small- | | | | | | | | | | | | | | |
| | diameter | | | | | | | | | | | | | | |
| | resolution | | | | | | | | | | | | | | |
| | Thick-film | A | B | B | B | B | A | B | C | C | A | A | C | A | A |
| | resolution | | | | | | | | | | | | | | |

The components shown in Table 1 are as follows.
(A) Alkali-soluble resin
Resin solution 1: The resin solution 1 of the carboxy group-containing photosensitive resin, which was obtained in Preparation Example 1, solid content: 71%
(B) Thermosetting resin
Epoxy resin: bisphenol A-type epoxy resin (N-870): manufactured by DIC Corporation, epoxy equivalent: 205 (g/eq)
(C) Photopolymerization Initiator
TPO-L: acylphosphine oxide compound, OMNIRAD TPO-L, manufactured by IGM Resins B. V.
JMT-784: titanocene compound, JMT-784, manufactured by Yueyang Kimoutain Scitech Co., Ltd.
(D) Colorant
Blue colorant: phthalocyanine blue, C.I. PIGMENT BLUE 15:3
Yellow colorant: C.I. PIGMENT YELLOW 147
(E) Inorganic Filler
Silica 1: D50 = 50 nm, YA050C, manufactured by Admatechs Co., Ltd.
Silica 2: D50 = 70 nm, spherical silica
Silica 3: D50 = 0.8 μm, SO-C2, manufactured by Admatechs Co., Ltd.
Barium sulfate: B-31, manufactured by Sakai Chemical Industry Co., Ltd., D50 = 0.3 μm
Photopolymerizable Monomer
NEOMER DA-600: dipentaerythritol hexaacrylate, manufactured by Sanyo Chemical Industries, Ltd.
Heat-Curing Catalyst
Heat-curing catalyst 1: melamine
Heat-curing catalyst 2: dicyandiamide
Additives
BYK-350: antifoaming agent, manufactured by BYK Japan K.K.
Polymerization inhibitor: QS-30, manufactured by Air Water Performance Chemical Inc.

### Measurement and Evaluation

### Transmittance

Each curable resin composition was applied onto a polyethylene terephthalate film (T-60, manufactured by Toray Industries, Inc., thickness: 38 μm) serving as a first film such that the resulting resin layer would have a post-curing thickness of 10 μm, and the thus applied curable resin composition was dried at 80° C. for 20 minutes to produce a dry film having the resin layer. The thus obtained dry film was laminated on a 1 mm-thick glass substrate, and a carrier film was peeled off to expose the resin layer. Further, the resin layer was irradiated with ultraviolet rays in a UV conveyor furnace at a cumulative exposure dose of 1,000 mJ/cm², and then heat-cured at 160° C. for 60 minutes, whereby an evaluation substrate having a 10 μm-thick cured product on the glass substrate was produced.

The transmittance of the thus produced cured product was measured by the following procedure. Using a UV-visible spectrophotometer and an integrating sphere apparatus (UV/VIS/NIR spectrometer V-570, manufactured by JASCO Corporation), the baseline in a range of 300 nm to 850 nm was measured, and the transmittance of the cured product of each evaluation substrate was subsequently measured. In the measurement, the scanning speed was set at 400 nm/min, and the scanning interval was set at 1 nm.

### Evaluation of Masking Property

### Production of Dry Film

Each curable resin composition was applied onto the entire surface of a polyethylene terephthalate film (T-60, manufactured by Toray Industries, Inc., thickness: 38 μm) serving as a first film such that the resulting resin layer would have a post-drying thickness of 10 μm, and the thus applied curable resin composition was dried at 80° C. for 20 minutes to form a resin layer. Subsequently, on this resin layer, a biaxially-stretched polypropylene film (cover film: OPP-FOA, manufactured by Futamura Chemical Co., Ltd.) was attached to produce a dry film.

### Production of Evaluation Substrate

A copper foil surface of an FR-4 copper-clad laminated board (100 mm×150 mm×0.8 mm, copper foil on both sides, copper foil thickness: 18 μm on both sides) was chemically polished with a polishing agent (CZ-8101B, manufactured by MEC Co., Ltd.) at an etching rate of 1 μm.

Subsequently, a second film was peeled off from each dry film to expose the resin layer of the dry film. The thus exposed resin layer on the second film side was attached to and laminated with the chemically-polished copper foil surface using a vacuum laminator (CVP-600, manufactured by Niko-Materials Co., Ltd.) under the conditions of a temperature of 80° C. to 110° C. and a pressure of 0.5 MPa.

Using a collimated light exposure apparatus equipped with a short arc-type high-pressure mercury lamp, the entire surface of the first film side was exposed through an exposure mask, and the first film was removed to expose the resin layer. The exposure dose was set at Step 4 of the Stouffer 41-Step Specifications when the exposure was performed on the first film in contact with the resin layer.

The exposed resin layer was developed for 60 seconds with a 1%-by-mass aqueous Na₂CO₃ solution under the conditions of 30° C. and a spray pressure of 2 kg/cm², subsequently irradiated with light at an exposure dose of 1,000 mJ/cm² in a UV conveyor furnace equipped with a high-pressure mercury lamp, and then heated at 160° C. for 60 minutes, whereby an evaluation substrate having a cured product was produced.

The thus obtained evaluation substrate was visually observed, and the masking property was evaluated in accordance with the following evaluation criteria. The results thereof are shown in Table 1.

### Evaluation Criteria for Masking Property

A: Copper color was not visible through the cured product.

B: Acceptable, although copper color was slightly visible through the cured product.

C: Copper color was visible through the cured product.

### Thin-Film Small-Diameter Resolution

A dry film was produced in the same manner as in the evaluation of masking property. Further, an evaluation substrate was produced in the same manner as the evaluation substrate used for the evaluation of masking property, except that the exposure was performed using a negative pattern having an opening diameter of 25 μm. The resin layer formed on the copper foil surface of the evaluation substrate had a thickness of 10 μm.

Cross-sections of openings of each evaluation substrate, which openings had a diameter of 25 μm, were observed under a scanning electron microscope (SEM) at a magnification of ×2,000. In the openings of each evaluation substrate, the opening diameter of the cured product surface in contact with the copper foil surface was defined as “bottom diameter” while the opening diameter of the other cured product surface was defined as “top diameter”, and the top diameter and the bottom diameter of each opening were measured. It is noted here that, for each of the top diameter and the bottom diameter of the openings, an arithmetic mean of the values measured at three spots was used.

For each opening, the difference between the top diameter and the bottom diameter (top diameter-bottom diameter) was calculated and evaluated based on the following evaluation criteria. A smaller value of [top diameter-bottom diameter] represents a straighter shape of the opening, while a larger value of [top diameter-bottom diameter] represents a more tapered shape of the opening. The straighter the shape of the opening, the higher the resolution is. The results are shown in Table 1.

### Evaluation Criteria for Thin-Film Small-Diameter Resolution

A: Top diameter-bottom diameter=0 μm to 5 μm

B: Top diameter-bottom diameter=more than 5 μm but 8 μm or less

C: Top diameter-bottom diameter=more than 8 μm

### Thick-Film Resolution

A dry film was produced in the same manner as in the evaluation of masking property, except that each curable resin composition was applied to the entire surface such that the resulting resin layer would have a post-drying thickness of 20 μm.

Further, an evaluation substrate was produced in the same manner as the evaluation substrate used for the evaluation of masking property, except that ABF GX-T31 (manufactured by Ajinomoto Fine-Techno Co., Inc.) was used as a base material, and that the exposure was performed using a negative pattern of L/S=100 μm/100 μm. The resin layer formed on the base material surface of the evaluation substrate had a thickness of 20 μm.

Cross-sections of 100-μm line pattern portions of each evaluation substrate were observed using an SEM. At a cross-section of each line pattern portion, the upper width of the line pattern portion was defined as “top length” while the lower width of the line pattern portion was defined as “bottom length”, and the top length and the bottom length of the line pattern portion were measured. It is noted here that, at a cross-section of a line pattern portion, the “lower width of the line pattern portion” is the width of a line pattern on the cured product surface that is in contact with the base material surface, and the width of the line pattern on the other cured product surface is the “upper width of the line pattern portion”.

For each line pattern portion, the difference between the top length and the bottom length (top length-bottom length) was calculated and evaluated based on the following evaluation criteria. A smaller value of [top length-bottom length] represents a straighter shape of the line pattern portion, while a larger value of [top length-bottom length] represents a more undercut shape of the line pattern portion. The results are shown in Table 1.

### Evaluation Criteria for Thick-Film Resolution

A: Top length-bottom length=0 μm to 10 μm

B: Top length-bottom length=more than 10 μm but 16 μm or less

C: Top length-bottom length=more than 16 μm

As shown in Table 1, the curable resin compositions according to Examples exhibited good masking property, thin-film small-diameter resolution, and thick-film resolution.

What is claimed is:

1. A curable resin composition, comprising:
an alkali-soluble resin;
a thermosetting resin;
a photopolymerization initiator;
an inorganic filler; and
a colorant,
wherein a 10 μm-thick cured product of the curable resin composition has a transmittance at a wavelength of 405 nm of 60% to 75%, and a transmittance at a wavelength of 650 nm of 45% to 62%.

2. The curable resin composition according to claim 1, wherein the inorganic filler has a volume-average particle size of 0.1 μm or less.

3. The curable resin composition according to claim 1, wherein a content percentage of the inorganic filler, calculated on a solid content basis, is 10% by mass to 50% by mass based on the total solid content of the curable resin composition.

4. The curable resin composition according to claim 1, wherein the inorganic filler contains a silicon oxide.

5. The curable resin composition according to claim 4, wherein a content percentage of the silicon oxide in the inorganic filler is 70% by mass to 100% by mass.

6. The curable resin composition according to claim 1, wherein a content percentage of the colorant, calculated on a solid content basis, is 0.70% by mass to 1.10% by mass based on the total solid content of the curable resin composition.

7. The curable resin composition according to claim 1, wherein a mass ratio of the content of the colorant to the content of the inorganic filler, each content being calculated on a solid content basis, is 0.015 to 0.05.

8. A dry film, comprising:
a first film; and
a resin layer laminated on the first film, the resin layer being a dry coating film of the curable resin composition according to claim 1.

9. A cured product of the curable resin composition according to claim 1.

10. A cured product of the resin layer of the dry film according to claim 8.

11. An electronic component, comprising the cured product according to claim 9.

12. An electronic component, comprising the cured product according to claim 10.

13. The curable resin composition according to claim 2, wherein the inorganic filler contains a silicon oxide.

14. The curable resin composition according to claim 2, wherein the inorganic filler contains a silicon oxide, and wherein a content percentage of the silicon oxide in the inorganic filler is 70% by mass to 100% by mass.

15. The curable resin composition according to claim 2, wherein a content percentage of the inorganic filler, calculated on a solid content basis, is 10% by mass to 50% by mass based on the total solid content of the curable resin composition, and wherein a mass ratio of the content of the colorant to the content of the inorganic filler, each content being calculated on a solid content basis, is 0.015 to 0.05.

16. The curable resin composition according to claim 2, wherein a content percentage of the colorant, calculated on a solid content basis, is 0.70% by mass to 1.10% by mass based on the total solid content of the curable resin composition, and wherein a mass ratio of the content of the colorant to the content of the inorganic filler, each content being calculated on a solid content basis, is 0.015 to 0.05.

17. The curable resin composition according to claim 3, wherein a mass ratio of the content of the colorant to the content of the inorganic filler, each content being calculated on a solid content basis, is 0.015 to 0.05.

18. The curable resin composition according to claim 6, wherein a mass ratio of the content of the colorant to the content of the inorganic filler, each content being calculated on a solid content basis, is 0.015 to 0.05.

19. The curable resin composition according to claim 1, wherein the colorant contains at least one blue colorant and at least one yellow colorant.

20. The curable resin composition according to claim 19, wherein the mass ratio of the content of the blue colorant to the content of the yellow colorant, each content being calculated on a solid content basis, is 1.0 to 2.0.
